(19) United States
(12) Patent Application Publication
(10) Pub. No.: US 2016/0257880 A1
(43) Pub. Date: Sep. 8, 2016

(54) ETCHANT COMPOSITION FOR TITANIUM NITRIDE LAYER AND METHOD FOR FORMING METAL WIRE USING THE SAME

(71) Applicant: Dongwoo Fine-Chem Co., Ltd., Jeollabuk-do (KR)

(72) Inventors: Hyung-Pyo Hong, Gyeonggi-do (KR); Jin-Seok Yang, Gwangju (KR); Hun-Pyo Hong, Jeollabuk-do (KR); Sang-Tae Kim, Jeollabuk-do (KR); Kyong-Ho Lee, Gyeonggi-do (KR)

(21) Appl. No.: 15/055,199

(22) Filed: Feb. 26, 2016

(30) Foreign Application Priority Data
Mar. 5, 2015 (KR) 10-2015-0030893

(51) Int. Cl. C09K 13/00; H01L 21/311

(52) U.S. Cl. CPC C09K 13/00; H01L 21/31111

(57) ABSTRACT

The present invention provides an etchant composition for a TiN layer including (A) at least one compound selected from sulfuric acid and alkyl sulfonic acid in 75% by weight to 95% by weight, (B) a peroxide in 0.3% by weight to 10% by weight, (C) an inorganic ammonium salt in 0.0001% by weight to 3% by weight, and (D) water in a residual quantity, and a method for forming a metal wire using the etchant composition.

### FIELD OF THE INVENTION

This application claims priority to and the benefits of Korean Patent Application No. 10-2015-0030893, filed with the Korean Intellectual Property Office on Mar. 5, 2015, the entire contents of which are incorporated herein by reference.

The present invention relates to an etchant composition for a titanium nitride (TiN) layer, and a method for forming a metal wire using the same.

### BACKGROUND OF THE INVENTION

Photoresist (PR) masks patterned using general photolithography have a high thickness and a high etch rate. In addition, the use of PR masks induces re-deposition on a side surface of a MTJ stack due to etching residue.

When a PR mask is used to form a pattern of a metal layer to be etched having a low etch rate, a high etch rate of the PR mask lowers etching selectivity for a metal layer to be etched having a low etch rate, and as a result, causes a low etch slope. Accordingly, such PR mask properties sometimes become a factor declining device properties and preventing high integration.

In order to address such problems of PR masks, technologies using hard masks have been currently used. TiN thin films and the like are being used as the hard mask material.

Etching for the TiN hard mask is carried out using an inductively coupled plasma reactive ion etching (ICPRIE) apparatus and the like using high-density plasma.

As a wet etching method for the TiN hard mask, Korean Patent No. 1282177 discloses an etchant for titanium-based metals, tungsten-based metals, titanium-tungsten-based metals or nitrides thereof including hydrogen peroxide, an organic acid salt, ammonia and water. However, wet etching methods for a TiN hard mask besides the above-mentioned method are not well known. Particularly, wet etching methods for a TiN hard mask having high selectivity for a metal layer or a metal wire including tungsten have not been reported.

Accordingly, wet etching methods for a TiN hard mask, and wet etching methods for a TiN hard mask having high selectivity for a metal layer or a metal wire including tungsten have been required.

### PRIOR ART DOCUMENTS

### Patent Documents

Korean Patent No. 1282177

### SUMMARY OF THE INVENTION

The present invention has been made in view of the above, and an object of the present invention is to provide an etchant composition for a TiN layer capable of efficiently wet etching the TiN layer.

Another object of the present invention is to provide an etchant composition for a TiN layer having high selectivity for a metal layer or a metal wire including tungsten.

Another object of the present invention is to provide an etchant composition for a TiN layer capable of selectively etching a TiN layer without giving damage to low-k materials such as TEOS and organosilicate glasses (OSG) as well as high-k materials such as SiNx, SiOx, poly Si, HfOx and ZrOx, main layers forming a semiconductor.

Another object of the present invention is to provide a method for forming a metal wire using the etchant composition for a TiN layer such as above.

An aspect of the present invention provides an etchant composition for a TiN layer including (A) at least one compound selected from sulfuric acid and alkyl sulfonic acid in 75% by weight to 95% by weight, (B) a peroxide in 0.3% by weight to 10% by weight, (C) an inorganic ammonium salt in 0.0001% by weight to 3% by weight, and (D) water in a residual quantity.

Another aspect of the present invention provides a method for forming a metal wire using, when a metal layer or a metal wire including tungsten (W) is present below, a TiN layer as a hard mask thereabove, the method including selectively etching the TiN layer hard mask with respect to the metal layer or the metal wire including tungsten (W), wherein the etching is carried out using the etchant of the present invention.

### DETAILED DESCRIPTION OF THE EMBODIMENTS

The present invention relates to an etchant composition for a TiN layer including (A) at least one compound selected from sulfuric acid and alkyl sulfonic acid in 75% by weight to 95% by weight, (B) a peroxide in 0.3% by weight to 10% by weight, (C) an inorganic ammonium salt in 0.0001% by weight to 3% by weight, and (D) water in a residual quantity.

The TiN layer means a layer formed with TiN regardless of its use. For example, the TiN layer may form a metal wire, or may be used as a TiN hard mask.

The etchant composition for a TiN layer may be useful for selectively etching the TiN layer in the presence of a metal layer or a metal wire including tungsten (W).

In the etchant composition for a TiN layer of the present invention, a selective etching ratio for the TiN layer with respect to the metal layer or the metal wire including tungsten (W) is 8:1 or greater.

In the etchant composition for a TiN layer of the present invention, a weight ratio of the at least one compound selected from sulfuric acid and alkyl sulfonic acid (A) and the peroxide component (B) is preferably from 100:0.32 to 100:7.0 and more preferably from 100:2 to 100:4. When the weight ratio is outside the above-mentioned range, the TiN/W etching selectivity may not be 8 or higher, or an etch rate for the TiN becomes too low causing an increase in the process time, which adversely affects process throughput.

In the etchant composition for a TiN layer of the present invention, the at least one compound selected from sulfuric acid and alkyl sulfonic acid (A) perform a function of controlling an etch amount and selectivity of the TiN layer and the W layer.

The alkyl sulfonic acid may be selected from among methanesulfonic acid, ethanesulfonic acid, propanesulfonic acid and butanesulfonic acid, and these may be used either alone as one type, or a combination of two or more types.

Sulfuric acid may be more preferably used among the (A) components.

The at least one compound selected from sulfuric acid and alkyl sulfonic acid (A) are included in 75% by weight to 95% by weight and more preferably in 80% by weight to 90% by weight with respect to the total weight of the composition. When the components are included in less than 75% by weight, content of the peroxide and the water relatively increases and an etch rate for the W increases causing a problem of reducing the etching selectivity of TiN/W, and when included in greater than 95% by weight, an etch rate for the TiN becomes too low causing a problem in the process yield, which is not preferable.

The peroxide (B) in the present invention performs a role of increasing an etch rate for the TiN, and controlling an etch rate for the tungsten layer as required in the process by oxidizing the tungsten layer.

The peroxide may be selected from among hydrogen peroxide (H₂O₂), tert-butyl hydroperoxide, lauroyl peroxide, tert-butyl peracetate, tert-butyl peroxybenzoate, methyl ethyl ketone peroxide, benzoyl peroxide, dicumyl peroxide and the like, and these may be used either alone as one type or as a combination of two or more types.

Among the peroxides, hydrogen peroxide may be more preferably used. The peroxide (B) is included in 0.3% by weight to 10% by weight and more preferably in 1% by weight to 5% by weight with respect to the total weight of the composition. When the component is included in less than 0.3% by weight, an etch rate for the TiN becomes too low causing a problem in the process yield, and when included in greater than 10% by weight, selective etching for the TiN layer becomes difficult, which is not preferable.

The inorganic ammonium salt (C) in the present invention performs a role of preventing tungsten oxidation caused by hydrogen peroxide or peroxides, and reducing an etch rate for the tungsten. Accordingly, the inorganic ammonium salt (C) performs a role of increasing etching selectivity for TiN/W.

The inorganic ammonium salt (C) may be selected from among, for example, ammonium phosphate, ammonium sulfate, ammonium nitrate, ammonium borate, ammonium persulfate and the like, and these may be used either alone as one type, or a combination of two or more types. Particularly, ammonium sulfate is more preferable compared to other inorganic ammonium salts since it performs a role of preventing tungsten oxidation and thereby increases TiN/W selectivity while decreasing an etch rate for W to protect, and as a result, provides a significant effect in terms of increasing a process margin.

As the inorganic ammonium salt (C), ammonium fluoride may cause a problem of declining electrical properties of a device by etching high-k materials such as SiOx, poly Si, HfOx and ZrOx, or low-k materials such as TEOS and OSG, and therefore, the use may be ruled out.

The inorganic ammonium salt (C) may be included in 0.0001% by weight to 3% by weight and more preferably in 0.001% by weight to 1% by weight. When the inorganic ammonium salt is included in less than 0.0001% by weight, an etch rate for the tungsten may not be reduced, and when included in greater than 3% by weight, the ammonium salt becomes recrystallized during a single tool treatment providing a cause for particle defects.

The water (D) in the etchant composition for a TiN layer of the present invention is not particularly limited, however, using deionized water is preferable, and using deionized water having a specific resistance value, a value showing the degree of ion removal in water, of 18 MΩ/cm or greater is more preferable.

The etchant composition for a TiN layer of the present invention may further include, in addition to the above-mentioned components, common additives, and the additive may include a corrosion inhibitor, a metal ion chelating agent, a surfactant and the like. In addition, the additive is not limited thereto, and various other additives known in the art may be selected and used in order to further improve effects of the present invention.

The at least one compound selected from sulfuric acid and alkyl sulfonic acid (A), the peroxide (B), the inorganic ammonium salt (C), the additives and the like used in the present invention may be prepared using methods commonly known in the art, and the composition for etching of the present invention preferably has a purity level for a semiconductor process.

In addition, the present invention provides a method for forming a metal wire using, when a metal layer or a metal wire including tungsten (W) is present below, a TiN layer as a hard mask thereabove, the method including selectively etching the TiN layer hard mask with respect to the metal layer or the metal wire including tungsten (W), wherein the etching is carried out using the etchant of the present invention.

Descriptions on the etchant composition for a TiN layer made above may also apply in the method for forming a metal wire.

In the method for forming a metal wire, a selective etching ratio for the upper TiN hard mask with respect to the lower metal layer or metal wire including tungsten is 8:1 or higher.

Hereinafter, the present invention will be described in more detail with reference to examples. However, the following examples are provided for more specifically describe the present invention, and the scope of the present invention is not limited to the following examples. The following examples may be properly modified or changed by those skilled in the art within the scope of the present invention.

### EXAMPLES 1 TO 12 AND COMPARATIVE EXAMPLES 1 to 6

Preparation of Etchant Composition for TiN Layer

Etchant compositions for a TiN layer of Examples 1 to 12 and Comparative Examples 1 to 6 were prepared in the compositions and the content listed in the following

Tables 1 and 2. In the following examples and the comparative examples, 96% sulfuric acid and 31% hydrogen peroxide were used as the sulfuric acid and the hydrogen peroxide, and content thereof was calculated as pure sulfuric acid and hydrogen peroxide content (net content), and listed in Table 1.

TABLE 1

| | Sulfuric Acid/Alkyl | | Hydrogen | | | | |
|---|---|---|---|---|---|---|---|
| | Sulfonic Acid | | Peroxide/Peroxide | | Ammonium Salt | | DIW |
| | Type | Content (%) | Type | Content (%) | Type | Content (%) | Content (%) |
| Example 1 | Sulfuric Acid | 87.5 | Hydrogen | 2.5 | AS | 0.01 | 9.99 |
| | | | Peroxide | | | | |
| Example 2 | Sulfuric Acid | 87.5 | Hydrogen | 2.5 | APM | 0.01 | 9.99 |
| | | | Peroxide | | | | |
| Example 3 | Sulfuric Acid | 87.5 | Hydrogen | 2.5 | AN | 0.01 | 9.99 |
| | | | Peroxide | | | | |
| Example 4 | Sulfuric Acid | 87.5 | Hydrogen | 2.5 | AS | 0.001 | 9.999 |
| | | | Peroxide | | | | |
| Example 5 | Sulfuric Acid | 87.5 | Hydrogen | 2.5 | AS | 0.05 | 9.95 |
| | | | Peroxide | | | | |
| Example 6 | Sulfuric Acid | 87 | Hydrogen | 2.5 | AS | 1 | 9.5 |
| | | | Peroxide | | | | |
| Example 7 | Sulfuric Acid | 80 | Hydrogen | 5 | AS | 0.01 | 14.99 |
| | | | Peroxide | | | | |
| Example 8 | Sulfuric Acid | 95 | Hydrogen | 0.3 | AS | 0.01 | 4.69 |
| | | | Peroxide | | | | |
| Example 9 | MSA | 87.5 | TBHP | 2.5 | AS | 0.01 | 9.99 |
| Example 10 | MSA | 87.5 | MEKP | 2.5 | AS | 0.01 | 9.99 |
| Example 11 | Sulfuric Acid | 87.5 | Hydrogen | 2.5 | APS | 0.01 | 9.99 |
| | | | Peroxide | | | | |
| Example 12 | Sulfuric Acid | 87.5 | TBHP | 2.5 | APS | 0.01 | 9.99 |
| Comparative | Sulfuric Acid | 87.5 | Hydrogen | 2.5 | — | — | 10 |
| Example 1 | | | Peroxide | | | | |
| Comparative | MSA | 87.5 | TBHP | 2.5 | — | — | 10 |
| Example 2 | | | | | | | |
| Comparative | Sulfuric Acid | 83.5 | Hydrogen | 2.3 | AS | 5 | 9.2 |
| Example 3 | | | Peroxide | | | | |
| Comparative | Sulfuric Acid | 70 | Hydrogen | 2.5 | AS | 0.01 | 27.49 |
| Example 4 | | | Peroxide | | | | |
| Comparative | Sulfuric Acid | 96 | Hydrogen | — | AS | 0.01 | 3.99 |
| Example 5 | | | Peroxide | | | | |
| Comparative | Sulfuric Acid | 87.5 | Hydrogen | 2.5 | TMAH | 0.01 | 9.99 |
| Example 6 | | | Peroxide | | | | |

(Unit: % by weight)
[Note]
AS: ammonium sulfate
APS: ammonium persulfate
APM: ammonium phosphate
AN: ammonium nitrate
MSA: methanesulfonic acid
TBHP: tert-butylhydroperoxide
MEKP: methyl ethyl ketone peroxide
TMAH: tetramethylammonium hydroxide

Test Example: Evaluation on Etching Property

A substrate formed with TiN, W, SiNx, SiOx, poly Si and HfOx layers was immersed in the etchant composition of Example 1 to Example 12 and Comparative Example 1 to Comparative Example 6 for 5 minutes at 75° C. An etch rate for each layer of the substrate was determined by measuring a change in the layer thickness using an ellipsometer (SE-MG-1000), and the results are shown in the following Table 2. The unit of the values listed below is Å/min.

TABLE 2

| Category | TiN | W | TiN/W | SiNx | SiOx | Poly Si | HfOx | TEOS | Solubility |
|---|---|---|---|---|---|---|---|---|---|
| Example 1 | 42.0 | 4.0 | 10.5 | <0.1 | <0.1 | <0.1 | <0.1 | <0.1 | Favorable |
| Example 2 | 40.0 | 5.0 | 8.0 | <0.1 | <0.1 | <0.1 | <0.1 | <0.1 | Favorable |
| Example 3 | 41.0 | 5.0 | 8.2 | <0.1 | <0.1 | <0.1 | <0.1 | <0.1 | Favorable |
| Example 4 | 40.0 | 5.0 | 8.0 | <0.1 | <0.1 | <0.1 | <0.1 | <0.1 | Favorable |
| Example 5 | 40.0 | 4.0 | 10.0 | <0.1 | <0.1 | <0.1 | <0.1 | <0.1 | Favorable |
| Example 6 | 36.0 | 4.0 | 9.0 | <0.1 | <0.1 | <0.1 | <0.1 | <0.1 | Favorable |
| Example 7 | 24.0 | 2.8 | 8.6 | <0.1 | <0.1 | <0.1 | <0.1 | <0.1 | Favorable |
| Example 8 | 16.0 | 1.9 | 8.4 | <0.1 | <0.1 | <0.1 | <0.1 | <0.1 | Favorable |
| Example 9 | 14.4 | 1.7 | 8.5 | <0.1 | <0.1 | <0.1 | <0.1 | <0.1 | Favorable |
| Example 10 | 13.2 | 1.5 | 8.8 | <0.1 | <0.1 | <0.1 | <0.1 | <0.1 | Favorable |
| Example 11 | 56.0 | 7.0 | 8.0 | <0.1 | <0.1 | <0.1 | <0.1 | <0.1 | Favorable |
| Example 12 | 42.0 | 4.6 | 9.1 | <0.1 | <0.1 | <0.1 | <0.1 | <0.1 | Favorable |
| Comparative | 45.0 | 8.0 | 5.6 | <0.1 | <0.1 | 2.0 | <0.1 | <0.1 | Favorable |
| Example 1 | | | | | | | | | |
| Comparative | 15.5 | 2.5 | 6.2 | <0.1 | <0.1 | 1.0 | <0.1 | <0.1 | Favorable |
| Example 2 | | | | | | | | | |
| Comparative | 32.0 | 4.0 | 8.0 | <0.1 | <0.1 | <0.1 | <0.1 | <0.1 | Precipitation |
| Example 3 | | | | | | | | | |
| Comparative | 88.0 | 16.0 | 5.5 | <0.1 | <0.1 | <0.1 | <0.1 | <0.1 | Favorable |
| Example 4 | | | | | | | | | |
| Comparative | 5.0 | 0.8 | 6.3 | <0.1 | <0.1 | <0.1 | <0.1 | <0.1 | Favorable |
| Example 5 | | | | | | | | | |
| Comparative | 40.0 | 7.2 | 5.5 | <0.1 | <0.1 | <0.1 | <0.1 | <0.1 | Favorable |
| Example 6 | | | | | | | | | |

(Unit: Å/min)

Based on Table 2, it was identified that, in the etchant compositions for a TiN layer of Examples 1 to 12, an etch rate higher than a certain level was obtained for the TiN layer and the W layer, etching selectivity for the TiN/W was 8 or higher, and a thickness of the low-k layers such as SiNx, SiOx, poly Si, HfOx and TEOS, main layers of a semiconductor, did not change before and after the treatment with the composition. Particularly, Example 1 and Example 5 had TiN/W etching selectivity of 10 or higher and exhibited significant effects among the examples.

Meanwhile, in Comparative Example 1, Comparative Example 2, and Comparative Example 4 to Comparative Example 6, target TiN/W selectivity was not obtained, and particularly in Comparatives Examples 1 and 2, defects were identified in the Poly Si layer. In Comparative Example 3, target etching properties were obtained, however, a problem of AS precipitation occurred when using a single tool. In Comparative Example 5, an etch rate for the TiN was too low.

The etchant composition for a TiN layer of the present invention enables efficient wet etching for a TiN layer.

In addition, the etchant composition for a TiN layer of the present invention has high selectivity for a metal layer or a metal wire including tungsten, and therefore, is capable of selectively etching a TiN layer even when a metal layer or a metal wire including tungsten is formed.

Furthermore, the etchant composition for a TiN layer of the present invention is capable of selectively etching a TiN layer without giving damage to low-k materials such as TEOS and organosilicate glasses (OSG) as well as high-k materials such as SiNx, SiOx, poly Si, HfOx and ZrOx, main layers forming a semiconductor.

In addition, the etchant composition for a TiN layer of the present invention is particularly very useful in etching a TiN hard mask.

What is claimed is:

1. An etchant composition for a TiN layer comprising:
(A) at least one compound selected from sulfuric acid and alkyl sulfonic acid in 75% by weight to 95% by weight;
(B) a peroxide in 0.3% by weight to 10% by weight;
(C) an inorganic ammonium salt in 0.0001% by weight to 3% by weight; and
(D) water in a residual quantity.

2. The etchant composition for a TiN layer of claim 1, used for selectively etching the TiN layer in the presence of a metal layer or a metal wire including tungsten (W).

3. The etchant composition for a TiN layer of claim 1, wherein a selective etching ratio for the TiN layer with respect to a metal layer or a metal wire including tungsten (W) is 8:1 or higher.

4. The etchant composition for a TiN layer of claim 1, wherein a weight ratio of the (A) component and the (B) component is from 100:0.32 to 100:7.0.

5. The etchant composition for a TiN layer of claim 1, wherein the alkyl sulfonic acid is at least one selected from the group consisting of methanesulfonic acid, ethanesulfonic acid, propanesulfonic acid and butanesulfonic acid.

6. The etchant composition for a TiN layer of claim 1, wherein the peroxide is at least one selected from the group consisting of hydrogen peroxide (H₂O₂), tert-butylhydroperoxide, lauroyl peroxide, tert-butyl peracetate, tert-butyl peroxybenzoate, methyl ethyl ketone peroxide, benzoyl peroxide and dicumyl peroxide.

7. The etchant composition for a TiN layer of claim 1, wherein the inorganic ammonium salt is at least one selected from the group consisting of ammonium phosphate, ammonium sulfate, ammonium nitrate, ammonium borate and ammonium persulfate.

8. The etchant composition for a TiN layer of claim 7, wherein the inorganic ammonium salt is ammonium sulfate.

9. A method for forming a metal wire using, when a metal layer or a metal wire including tungsten (W) is present at a lower part, a TiN layer as a hard mask thereabove, the method comprising:
selectively etching the TiN layer hard mask with respect to the metal layer or the metal wire including tungsten (W), wherein the etching is carried out using the etchant of claim 1.

10. The method for forming a metal wire of claim 9, wherein a selective etching ratio for the upper TiN hard mask with respect to the lower metal layer or the metal wire including tungsten (W) is 8:1 or higher.
